(19) United States
(12) Patent Application Publication
(10) Pub. No.: US 2024/0422941 A1
(43) Pub. Date: Dec. 19, 2024

(54) Novel 3D Artificial Intelligence Computer System

(71) Applicant: Banqiu Wu, Katy, TX (US)

(72) Inventor: Banqiu Wu, Katy, TX (US)

(21) Appl. No.: 18/772,211

(22) Filed: Jul. 14, 2024

(51) Int. Cl. H05K 7/20; H05K 7/02

(52) U.S. Cl. CPC H05K 7/20281; H05K 7/023

(57) ABSTRACT

A novel 3D AI computer system is disclosed. It is a 3D chip stack comprising a GPU and/or CPU, thermoelectric-cooler, high bandwidth memory chip, and TSV interconnections. It has a higher number of interconnections, higher data communication rate, and more compact structure. The heat generated in the chip stack is dissipated by the thermoelectric-cooler.

### FIELD

The embodiments of the present disclosure generally relate to an artificial intelligence (AI) computer system. More particularly, embodiments of the present disclosure relate to a three-dimensional (3D) integrated AI computer system with self-cooled integrated circuit (IC).

### BACKGROUND

Recently, AI technologies have become the most competitive ones in the world. It is predicted that AI will have more and more applications in the future. AI applications in autopilot, face identification, expert systems, medical diagnosis, military weapons, etc. have been validated. Economically, it is believed that the market size for applications of AI is as high as one trillion dollars per year in the future. Therefore, more and more powerful AI systems are in demand.

Current AI systems have a special machine learning capability, which makes it different from previous modeling systems. The AI application feasibility depends on calculation speed, data transfer rate, and data size, all of which heavily rely on the microchip's performance. It is the semiconductor manufacturing technology advancements in recent years that make the graphics processing unit (GPU) very powerful. Presently, GPU technologies have made revolutionary changes in AI capability that usher us into a new era of AI.

AI's specialty is its learning or training capability, which is based on big data. This means that AI necessitates working in conjunction with a large data center. Because AI's applications cover a broad range of areas in people's daily lives, industrial production, and almost every corner of our society, there will be strong demand in the future for a variety of AI ecosystems.

Current AI computer systems consist of a GPU, high bandwidth memory (HBM), dynamic random access memory (DRAM), and solid state drive (SSD). The interconnection data transfer fate between the GPU and high bandwidth memory became the most critical parameter for determining the performance of an AI computer system.

AI computer system performance heavily depends on the computer system calculation capability. Therefore, AI system performance is mainly determined by the system performance indicators such as transistor gate delay, interconnect delay, internal memory data transfer rate, and external memory data transfer rate.

In order to overcome the gate delay and increase memory size, smaller feature sizes of integrated circuits have been enhanced by different lithographic technologies. Since the 1980s, projection lithography has used increasingly shorter and shorter exposure wavelength for better IC resolution, from 436 am (g-line) to 365 nm (i-line), 248 nm (deep ultraviolet), 198 nm (deep ultraviolet), 193 nm immersion, to the current most advanced 13.5 nm (extremely ultraviolet, i.e. EUV) lithography.

Since 2000, gate delay has become less critical as interconnect delay in an IC has become more and more significant and as internal memory data transfer rate became relatively slow (also called the “memory wall”). To solve these challenges, more and more cores are used on GPU and CPU microchips. However, multiple core approaches for GPU and CPU have almost reached their current technological limit.

For the purpose of making faster computer systems, another approach to overcoming these limits is given more attention, namely, the three-dimensional (3D) stacking of ICS, which reduces interconnect delay and eliminates the memory wall because the 3D stacking of chips can provide a higher number of interconnects and shorten interconnect distances.

High bandwidth memory based on 3D IC stacking technology has been proposed and is now used in high end AI computer systems to allow for a high memory data transfer rate, but the data transfer rate between the GPU and high bandwidth memory is limited by the data bus. The more bits in the data bus, the higher the data transfer rate. However, the number of the bus bits is limited by the geometric dimensions of the microchip system. Currently, data busses reach as high as about 5000 bits, but higher bandwidth is in strong demand for AI computer system performance improvement.

The interposer, GPU, and 3D stacking of high bandwidth memory have been integrated for a high performance AI computer system via the data bus. However, it is very challenging to improve the AI system further by using the traditional data bus system due to geometric limits.

Therefore, 3D integration of GPU and high bandwidth memory is believed to have a good potential to significantly improve AI system performance because it can provide a much greater number of interconnects than the data bus and allow for a much shorter interconnect length. However, there has existed no technological solution to effectively dissipate the heat created in the 3D integrated AI system until now. The current advanced GPU consumes as much as 700 watts of electricity, making heat dissipation very challenging.

In this disclosure, a thermoelectric cooling device is monolithically formed on an IC. By using 3D stacking of the GPU and high bandwidth memory with thermoelectric cooling built into the stack, data transfer rates will be much faster than the current bus structure allows, and without heat dissipation issues.

Therefore, by using 3D stacking technology and the thermoelectric cooling method disclosed in this invention, AI computer system performance will be tremendously improved.

### SUMMARY

Devices of AI computer systems using thermoelectric-cooled IC are provided herein. In one embodiment, the AI computer system includes a 3D chip stack consisting of a thermoelectric-cooled GPU and a high bandwidth memory chip.

In one embodiment, a thermoelectric-cooler is fabricated on the same wafer as the IC. The cold side of the thermoelectric cooler is in the same area of the IC for the benefit of effectively dissipating the heat created by the IC. In addition, the hot side can be dispensed into a heat exchanger where cooling fluid can take heat out of the AI computer area.

One important property of the AI computer system disclosed here is the separation of the hot side and cold side of the thermoelectric cooling device as well as the in site cold side of the IC. This architecture has the capability to dissipate the heat created in the ICs and enable the arrangement of more connections between ICs in a 3D stacking.

Current data transfer connections between ICs use the data bus and the data transfer rate depends on the number of bits in the data bus. For the most advanced AI system, the data bus has several thousand bits. In comparison, the number of TSV connections between a thermoelectric-cooled IC and a memory chip could be 10 to 50 times higher, unlocking much greater AI computer performance.

This invention makes it possible for the AI computer system to become a vertical stack of different modules such as the CPU/GPU module, memory module, supporting module with power ICs, and input/output module. This new AI computer system structure will allow for a very compact structure with reliability and calculation power like never before.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 depict one embodiment of a thermoelectric-cooled GPU chip in accordance with one embodiment of the invention;

FIG. 2 depict one embodiment of 3D stacked computer system with thermoelectric-cooled chip and a memory chip in accordance with one embodiment of the invention.

### DETAILED DESCRIPTION

Embodiments of the present invention generally provide apparatus for integrating AI computer system. Particularly, embodiments of the present invention provide apparatus for integrated stacking of AI computer system with TSV and thermoelectric-cooled IC.

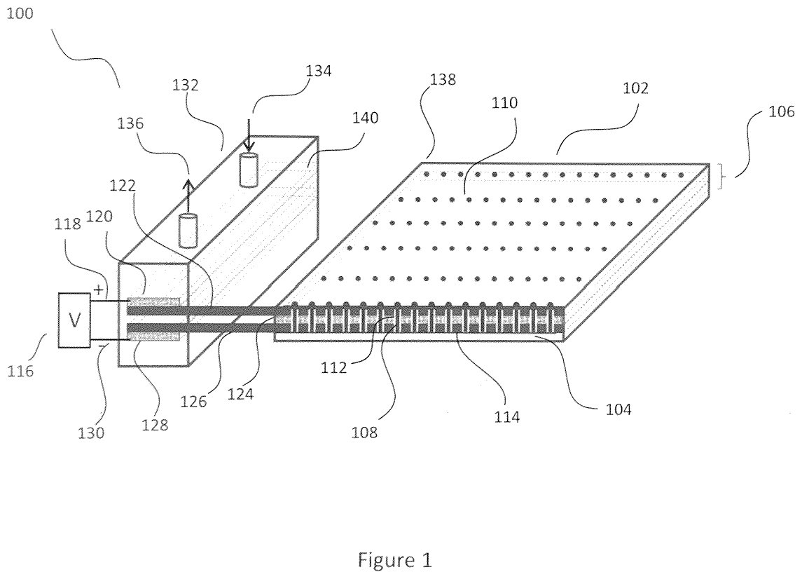

FIG. 1 schematically illustrates a thermoelectric-cooled GPU IC system 100 in accordance with one embodiment of the present invention. The GPU IC system 100 generally comprises a GPU 102. The GPU 102 is composed of IC layer 104 and thermoelectric cooler layer 106. IC layer 104 has semiconductor transistors to perform the IC function, as well as interconnections to electrically connect the transistors.

In one embodiment, thermoelectric-cooled GPU IC system 100 has a monolithic chip and IC layer is fabricated on the bulk silicon wafer by semiconductor processes such as patterning, implantation, etch, chemical-vapor deposition (CVD), physical-vapor deposition (PVD), chemical mechanical planarization (CMP), electrochemical deposition (ECD), thinning, cleaning, etc.

In one embodiment, IC layer is composed of three sub-layers. They are device sub-layer with transistors, interconnect sub-layer for connections, and bulk silicon sub-layer for physical support. After device sub-layer and interconnect sub-layer are formed, original wafer is thinned for 3D stacking purpose.

In one embodiment, TSV 108 is interconnected with IC layer 104 on one end and the other end is revealed TSV 110. Revealed TSV 110 is for connection with other device such as memory chip during three-dimensional stacking. TSV 108 has the diameter range of 3-30 micrometers with length range of 20-70 micrometers for geometrically providing higher number of TSVs than current interposer.

TSV 108 is fabricated on a hole by depositing copper as conductor. The hole is made by using plasma etch or laser. Dielectric liner 112 is deposited for insulation purpose by regular semiconductor processes such as PVD or CVD. After the dielectric liner 112 is formed, copper material of TSV 108 is deposited by using ECD process.

In one embodiment, thermoelectric cooler 114 is fabricated on the surface of IC layer 104 by using regular semiconductor processes such as PVD or CVD. The thermoelectric cooler 114 can be deposited on surface of interconnect sub-layer of IC layer 104, or on the surface of bulk silicon sub-layer of IC layer 104, or on the surfaces of both sub-layers.

In one embodiment, direct current (DC) power supply 116 provides DC current flowing through a loop. The OC current loop includes DC power supply 116, conductive wire 118, metal 120. N-type silicon 122, metal 124, P-type silicon 126, metal 128, and conductive wire 130.

In one embodiment, thermoelectric-cooled GPU IC system 100 has heat exchanger 132. Heat fluid flows into heat exchanger 132 from inlet 134 and flow out from 136, resulting in the final release of heat to environment.

In one embodiment, thermoelectric cooler 114 includes cold side 138 and hot side 140. When DC current flows in the loop mentioned above, temperature on cold side 138 becomes lower than the temperature on hot side 140. Hot side 140 is embedded in heat exchanger 132 to release heat to heat fluid by heat exchanging, and then heat is carried out of the thermoelectric-cooled GPU IC system 100 by flowing fluid. Heat created from IC layer 104 is dissipated to cold sides 138, resulting in the cooling of the GPU 102.

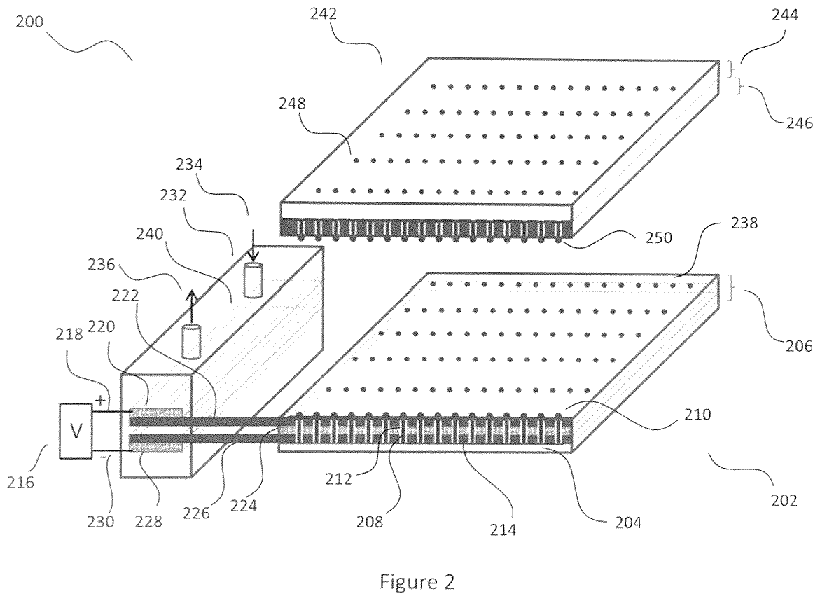

FIG. 2 shot s a stack 200 of thermoelectric-cooled GPU chip 202 and memory chip 242 in accordance with one embodiment of the present invention. The GPU 202 is composed of IC layer 204 and thermoelectric cooler layer 206. IC layer 204 has semiconductor transistors to perform the IC function, as well as interconnections to electrically connect the transistors.

In one embodiment, IC 200 is a monolithic chip and IC layer is fabricated on the bulk silicon wafer by semiconductor processes such as patterning, implantation, etch, CVD, PVD, CMP, ECO, thinning, cleaning, etc.

In one embodiment, IC layer is composed of three sub-layers. They are device sub-layer with transistors, interconnect sub-layer for connections, and bulk silicon sub-layer for physical support. After device sub-layer and interconnect sub-layer are formed, original wafer is thinned for 3D stacking purpose.

In one embodiment, TSV 208 is interconnected with IC layer 204 on one end and the other end is revealed TSV 210. Revealed TSV 210 is for connection with other device such as memory chip during three-dimensional stacking. TSV 208 has the diameter range of 3-30 micrometers with length range of 20-70 micrometers for geometrically providing higher number of TSVs than current interposer.

TSV 208 is fabricated on a hole by depositing copper as conductor. The hole is made by using plasma etch or laser. Dielectric liner 212 is deposited for insulation purpose by regular semiconductor processes such as PVD or CVD. After the dielectric liner 212 is formed, copper material of TSV 208 is deposited by using ECD process.

In one embodiment, thermoelectric cooler 214 is fabricated on the surface of IC layer 204 by using regular semiconductor processes such as PVD or CVD. The thermoelectric cooler 214 can be deposited on surface of interconnect sub-layer of IC layer 204, or on the surface of bulk silicon sub-layer of IC layer 204, or on the surfaces of both sub-layers.

In one embodiment, direct current (DC) power supply 216 provides DC current flowing through a loop. The DC current loop includes DC power supply 216, conductive wire 218, metal 220, N-type silicon 222, metal 224, P-type silicon 226, metal 228, and conductive wire 230.

In one embodiment, thermoelectric-cooled GPU IC 200 has heat exchangers 232. Heat fluid flows into heat exchanger 232 from inlet 234 and flow out from 236, resulting in the final release of heat to environment.

In one embodiment, thermoelectric cooler 214 includes cold side 238 and hot side 240. When DC current flows in the loop mentioned above, temperature on cold side 238 becomes lower than the temperature on hot side 240. Hot side 240 is embedded in heat exchanger 232 to release heat to heat fluid by heat exchanging, and then heat is carried out of the thermoelectric-cooled GPU IC system 200 by flowing fluid. Heat created from IC layer 204 is dissipated to cold sides 238, resulting in the cooling of the GPU chip 202.

In one embodiment, memory chip 242 has memory device layer 244, memory bulk silicon layer 246, and memory TSV 248. Memory TSV 248 is located in memory bulk silicon layer 246. Memory TSV 248 is interconnected with memory device layer 244 on one end and the other end is revealed memory TSV 250 on the surface of memory bulk silicon layer 246.

In one embodiment, GPU chip 202 and memory chip 242 are three-dimensionally stacked by metal bonding method such as metal thermo-compression between revealed TSV 210 of GPU chip 202 and revealed memory TSV 250 of memory chip 242. The bonding connects GPU chip 202 and memory chip 242 electrically, so that communication happens between GPU chip 202 and memory chip 242.

TSV 208 and memory TSV 248 have the diameter range of 3-30 micrometers with length range of 20-70 micrometers. The structure allows higher number of TSV number than current interposer and shorter distances of interconnection between GPU chip 202 and memory chip 242.

What is claimed is:

1. A self-cooled computer chip, comprising:
An integrated circuit;
A thermoelectric-cooler comprising a cold side and a hot side, wherein the cold side dissipates heat created from the integrated circuit;
A plurality of TSVs wherein a plurality of first ends of the TSVs is connected to the integrated circuit, a plurality of second ends of the TSVs is for external connections.

2. The self-cooled computer chip of claim 1, wherein the thermoelectric cooler is fabricated on the same silicon wafer as the integrated circuit by using of the semiconductor processes including patterning, implantation, etch, CVD, PVD, CMP, ECO, thinning and cleaning.

3. The self-cooled computer chip of claim 1, wherein the thermoelectric cooler is embedded.

4. The self-cooled computer chip of claim 1, wherein the hot side of the thermoelectric cooler is embedded in a heat exchanger wherein a liquid flows into the heat exchanger at a lower temperature and flow out of the heat exchanger at a higher temperature.

5. The self-cooled computer chip of claim 4, wherein a circulated liquid goes through the heat exchanger, dissipating heat to environment.

6. The self-cooled computer chip of claim 1, wherein the hot side and the cold side are connected by semiconductor;

7. The self-cooled computer chip of claim 1, wherein a power supply provides direct current flowing a loop including the cold side and the hot side of the thermoelectric cooler for making temperature at the cold side lower than temperature at the hot side of the thermoelectric-cooler.

8. The self-cooled computer chip of claim 1, wherein the TSV is a through-the-cold-side via.

9. A three-dimensional-stacked computer using thermoelectric cooling, comprising:
A processing unit chip;
A memory chip;
A plurality of TSVs wherein the TSVs interconnect the processing unit chip and the memory chip.

10. The three-dimensional-stacked computer of claim 9, wherein the three-dimensional-stacked computer is an artificial intelligence computer.

11. The three-dimensional-stacked computer of claim 9, wherein the processing unit chip and the memory chip are stacked by using the through-silicon via bonding connections.

12. The three-dimensional-stacked computer of claim 9, wherein the processing unit chip is a GPU chip comprising: an integrated circuit; a thermoelectric-cooler comprising a cold side and a hot side, wherein the cold side dissipates heat created from the integrated circuit; a plurality of through-silicon via wherein first ends are connected to the integrated circuit, second ends are connected to the memory chip.

13. The three-dimensional-stacked computer of claim 9, wherein the TSV is a through-the-cold-side via.

14. The three-dimensional-stacked computer of claim 9, wherein the memory chip is a high bandwidth memory chip comprising: a memory IC; a thermoelectric-cooler comprising a cold side and a hot side, wherein the cold side dissipates heat created from the integrated circuit; a plurality of through-silicon via wherein first ends are connected to the memory IC, second ends are connected to the processing unit chip.

15. The three-dimensional-stacked computer of claim 9, wherein the processing unit chip is a CPU chip comprising: an integrated circuit; a thermoelectric-cooler comprising a cold side and a hot side, wherein the cold side dissipates heat created from the integrated circuit, the hot side transfers heat to environment; a plurality of through-silicon via wherein first ends are connected to the integrated circuit, second ends are for external connection chip.

16. The three-dimensional-stacked computer system of claim 9, wherein the memory chip is a high bandwidth memory.

17. The three-dimensional-stacked computer of claim 9, wherein the memory chip is a DRAM chip.

18. The three-dimensional-stacked computer of claim 9, wherein the memory chip is a high bandwidth memory chip stack.

19. The three-dimensional-stacked computer of claim 9, wherein the processing unit chip is a GPU.

20. The three-dimensional-stacked computer of claim 9, wherein the processing unit chip is a CPU.
